(19) United States
(12) Patent Application Publication
(10) Pub. No.: US 2024/0360328 A1
(43) Pub. Date: Oct. 31, 2024

(54) METHOD OF STABILIZING PEROVSKITE INK AND A PEROVSKITE INK FORMULATION IN ACCORDANCE WITH THE METHOD

(71) Applicant: SOLAIRES ENTERPRISES INC., Victoria (CA)

(72) Inventors: Deepak GANGADHARAN, Victoria, BC (CA); Makhsud SAIDAMINOV, Victoria, BC (CA); Erin MOLONEY, Thetis Island, BC (CA)

(21) Appl. No.: 18/685,174

(22) PCT Filed: Aug. 25, 2022
(86) PCT No.: PCT/CA2022/051290

§ 371 Date: Feb. 20, 2024

(30) Foreign Application Priority Data
Aug. 25, 2021 (CA) 3128901

(51) Int. Cl. C09D 11/033; C09D 11/037; H10K 30/50; H10K 71/12; H10K 85/50

(52) U.S. Cl. CPC C09D 11/033; C09D 11/037; H10K 30/50; H10K 71/12; H10K 85/50

(57) ABSTRACT

A method of stabilizing perovskite ink, comprising the steps of preparing a perovskite ink using one or more solvents and adding to the perovskite ink a sulfur or sulfur based compound that interacts with amine groups in the perovskite ink to inhibit amine-water proton exchange. A perovskite ink, comprising precursor salts dissolved in one or more solvents that when deposited as a thin film crystallize to form the perovskite structure with an ‘ABX3’ composition in which: ‘A’ is a monovalent cation being one or more of methylammonium (MA+) and formamidinium (FA+). ‘B’ is a divalent cation, and ‘X’ is a halogen being one or more of F—, I—, Br— and Cl—; an additive selected from the group consisting of sulfur and sulfur based compounds that interacts with amine groups in the perovskite ink to inhibit amine-water proton exchange.

### FIELD

There is described a method of stabilizing perovskite ink so it can be used in applications such as the manufacture of perovskite solar cells and a perovskite ink formulation in accordance with the method.

### BACKGROUND

Perovskite ink can be used in different fields including but not limited to solar cells, displays and sensors. Unfortunately, conventional perovskite inks are unstable. The problem and a proposed solution will now be described in the context of solar cells.

An advantage of perovskite solar cells (PSCs) is the cost-effective and simple deposition of the solar absorber layer using solution-processable methods from a perovskite ink. The ink consists of precursor salts dissolved in solvent(s), which is deposited as a thin film and crystallized to form the perovskite structure with an ‘ABX3’ composition. ‘A’ is a monovalent cation (methylammonium (MA+), formamidinium (FA+) or Cs+), ‘B’ is a divalent cation (Pb2+ or Sn2+), and ‘X’ is a halogen (I—, Br— or Cl—). Given the high efficiencies demonstrated for small-area PSCs, significant efforts are being devoted to making commercially viable, large-area, stable, and high-efficiency devices. One of the remaining obstacles is the instability of conventional perovskite inks, particularly in ambient air: PSC performance depends on ink age in hours.

In aging perovskite inks, the detrimental oxidation of I- to I210 and reactions of the organic components including MA+, FA+, and solvent are major contributors to decomposition. Processing in ambient air, outside of an inert environment, increases the water content in ink, accelerating its degradation. In some cases, this is due to the hydrolysis of N,N-dimethylformamide (DMF) solvent to produce dimethylamine and formic acid; however, the degradation of perovskite inks containing FA+ or MA+/FA+ in dimethyl sulfoxide (DMSO) and DMF cosolvent, which does not involve DMF hydrolysis is also accelerated by water. The deleterious effect of humidity on perovskite inks is a major issue for upscaling PSC fabrication: to develop moisture-stable inks.

### SUMMARY

There is provided a method of stabilizing perovskite ink. The method involves adding to perovskite ink an additive which can interact with amine groups in the perovskite ink to inhibit amine-water proton exchange. Beneficial results have been obtained when the additive is elemental sulfur.

There are several solvents that can be used, including but not limited to one or more solvents selected from the group consisting of N-methyl-2-pyrrolidone (NMP), alkyl-2-pyrrolidone, N,N-dimethylformamide (DMF), dimethylsulfoxide (DMSO), dialkylformamide, γ-butyrolactone (GBL), 2-methylpyrazine (2-MB), 1-pentanol (1-P), 2-methoxyethanol (2-ME) and N, N′-Dimethylpropyleneurea (DMPU). The weight opercentage ratio of selected one or combination of solvents may range from 10-30% to achieve the final concentration of perovskite ink required for the formation of a perovskite thin film. We have determined that scalable perovskite ink containing mixed cations (3 FA+: 1 MA+) in NMP and DMF (abbreviated as “MC-NMP”) degrades via reaction of MA with FA+ in hours: that water increases the reactivity of MA+ by accelerating proton exchange between MA+ and MA. However, the addition of elemental sulfur (S8) slows this proton exchange process via sulfur-amine interactions, decreasing the reactivity of MA+.

In addition to elemental sulfur, other additives such as L-α-phosphatidylcholine may be used.

The best performance happens when the ratio of NMP to DMF solvents is 30 to 70.

Perovskite ink preferably includes one or more additives selected from the group consisting of sulfur or sulfur based compound may be added for stabilization of ink. Examples of other additives to stabilize the ink are triethyl borate, 18-crown-6, ITIC-Th and phenylboric acid. The additive may be added in the concentration of about 0.001M to about 0.1M. Sulfur-stabilized MC-NMP ink (abbreviated as “MC-NMP-S8”) shows minimal degradation of the organic components for a minimum of three months of aging at room temperature in ambient air.

PSCs fabricated from MC-NMP-S8 inks aged for over one month had comparable performances to PSCs made from fresh MC-NMP ink, and demonstrates the viability of use of MC-NMP-S8 ink to fabricate large area PSCs by blade coating.

The degradation of MC-NMP ink showed minimum degradation at temperature range from −10 C to +85 C.

### BRIEF DESCRIPTION OF THE DRAWINGS

These and other features will become more apparent from the following description in which reference is made to the appended drawings, the drawings are for the purpose of illustration only and are not intended to be in any way limiting, wherein:

FIG. 1A is a photographic image of films made from MC-NMP ink aged for 0 and 28 hours.

FIG. 1B and FIG. 1C are XRD and H NMR spectra of MC-NMP ink in dimethyl sulfoxide-d6 (DMSO-d6) aged for 0 and 28 hours.

FIG. 1D are formula disclosing proposed mechanisms for the reactions of MA with FA+ and MFA+.

FIG. 1E is a graph disclosing percentage of MA+ remaining after aging at ˜20-30% relative humidity (RH) and ˜40% RH, relative to MA+ in fresh MC-NMP ink (˜20-30% RH), calculated from the MA+CH3 resonance. The half-lives of MA+ at ˜20-30% and ˜40% RH are approximately 14 hours and 9 hours, respectively.

FIG. 2A is a graph showing an amine-water proton exchange with the 1H NMR H2O resonance is broad in solutions containing MA+ and/or FA+ (inset), and narrow in spectra of solutions which do not contain MA+ or FA+ (black trace).

FIG. 2B is a graph shown the amine-water proton exchange process—a proton is transferred from an alkylammonium to water, and water to an alkylamine.

FIG. 3 are photographic images of stabilized films made from MC-NMP-S8 ink aged for 0 and 124 days.

FIG. 3B a graph of XRD of films made from MC-NMP-S8 ink aged for between 0 and 124 days (normalized intensities).

FIG. 3C is a graph of 1H NMR spectra of MC-NMP-S8 ink in DMSO-d6 after 0 and 124 days of aging.

FIG. 3D is a graph of percentage of initial MA+ remaining as a function of ink age, calculated from integrations of the MA+CH3 resonance.

FIG. 4A is a graph of interactions of S8 additive with amines in MC-NMP ink before and after aging for 6 hours: images of the inks, and corresponding appearances of the N—H and H2O 1H NMR resonances.

FIG. 4B is a graph of change in chemical shift of the N—H resonance as a function of ink age.

FIG. 4C discloses formula for amine-sulfur complexes in aged MC-NMP-S8 ink (upper), as opposed to the degradation of aged MC-NMP ink (lower).

FIG. 5A is a graph of current density-Voltage (J-V) curve of a perovskite solar cell (PSC) fabricated by spin coating MC-NMP-S8 ink aged for 5 days in ambient air, photovoltaic parameters are shown for the reverse scan.

FIG. 5B is a graph of power conversion efficiency (PCE) for an aperture area of 0.4 cm2 as a function of the ink age used to fabricate PSCs (by spin coating) (Note: Non-perovskite films were obtained from aged MC-NMP, as shown in FIG. 1).

FIG. 5C is a graph of J-V curve of PSC fabricated by blade coating fresh MC-NMP-S8 ink, photovoltaic parameters are shown for the reverse scan.

FIG. 5D is a graph of PCE as a function of aperture area for the measurement of devices fabricated by blade coating fresh MC-NMP-S8 ink.

FIG. 6 shows images of films made from MC-NMP ink containing different weight ratios of NMP to DMF, and annealed at 150° C. for 1, 3, or 5 minutes.

FIG. 7 shows XRD of films shown in FIG. 6.

FIG. 8 shows XRD of films made from MC-NMP ink aged for 0, 1, and 2 days at ˜20-30% RH (XRD of films from MC-NMP aged at 40% RH shown in FIG. 1B).

FIG. 9 shows XRD of a film made from fresh MC-NMP ink, after aging the film for 8 days in ambient air. The film had partially converted from black to yellow before XRD analysis.

FIG. 10 shows 1H NMR of fresh MC-NMP ink.

FIG. 11 shows 1H NMR of MC-NMP ink aged 24 hours at ˜20-30% RH.

FIG. 12 shows 1H NMR of MC-NMP ink aged 5 days (121 hours) at ˜20-30% RH.

FIG. 13 shows 1H NMR of MC-NMP ink aged 6 hours at ˜40% RH.

FIG. 14 shows 1H NMR of MC-NMP ink aged 28 hours at ˜40% RH.

FIG. 15 shows 1H NMR of 16% dimethylamine in H2O, in a solution of PbI2, PbBr2, NMP and DMF.

FIG. 16 shows 1H NMR of N-methylformamide in PbI2, PbBr2, NMP and DMF.

FIG. 17 shows 1H NMR of PbI2, PbBr2, NMP and DMF.

FIG. 18 shows 1H NMR of FAI in DMF.

FIG. 19 shows 1H NMR of MABr in DMF.

FIG. 20 shows 1H NMR of MACI in DMF.

FIG. 21 shows XRD of films made from MC-NMP ink aged for 0 and 1 day containing 0.001 M NH4Cl additive.

FIG. 22 shows 1H NMR of MC-NMP ink aged 85 days containing 0.001 M NH4Cl additive.

FIG. 23 shows XRD of films made from MC-NMP ink aged 0 and 1 day with 0.001 M CH3COONH4 additive.

FIG. 24 shows 1H NMR of MC-NMP ink aged 84 days containing 0.001 M CH3COONH4 additive.

FIG. 25 shows XRD of films made from MC-NMP ink aged 0 and 1 day with 0.001 M dibenzo-18-crown-6 additive.

FIG. 26 shows 1H NMR of MC-NMP ink aged 1 day containing 0.001 M dibenzo-18-crown-6.

FIG. 27 shows 1H NMR of fresh MC-NMP-S8 ink.

FIG. 28 shows 1H NMR of MC-NMP-S8 ink aged 1 day at ˜20% RH.

FIG. 29 shows 1H NMR of MC-NMP-S8 ink aged 6 hours at ˜40% RH.

FIG. 30 shows 1H NMR of MC-NMP-S8 ink aged 31 days at ˜20-30% RH

FIG. 31 shows 1H NMR of MC-NMP-S8 ink aged 124 days at ˜20-55% RH.

FIG. 32 shows 1H NMR of fresh MC-NMP-S8 ink containing 1 M H2O.

FIG. 33 shows 1H NMR of MC-NMP-S8 ink aged 1 day containing 1 M H2O.

FIG. 34 shows 1H NMR of MC-NMP-S8 ink aged 25 days containing 1 M H2O.

FIG. 35 shows XRD of films made from aging MC-NMP-S8, actual peak intensities (normalized peak intensities shown in FIG. 3).

FIG. 36 shows XRD of film made from MC-NMP-S8 aged for 124 days (starting from 5°)

FIG. 37 shows J-V curve of PSC fabricated by spin coating fresh MC-NMP ink, photovoltaic parameters are shown for the reverse scan.

FIG. 38 shows absorbance of fresh films made from 3 ages of MC-NMP-S8 ink.

FIG. 39 shows PL of fresh films made from 3 ages of MC-NMP-S8 ink.

### DETAILED DESCRIPTION

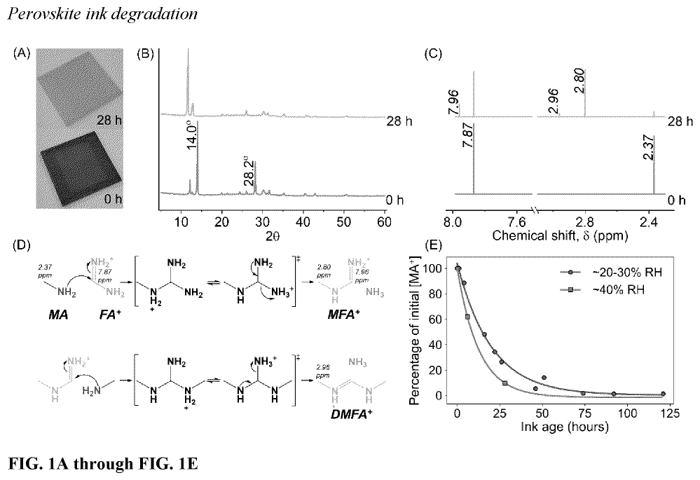

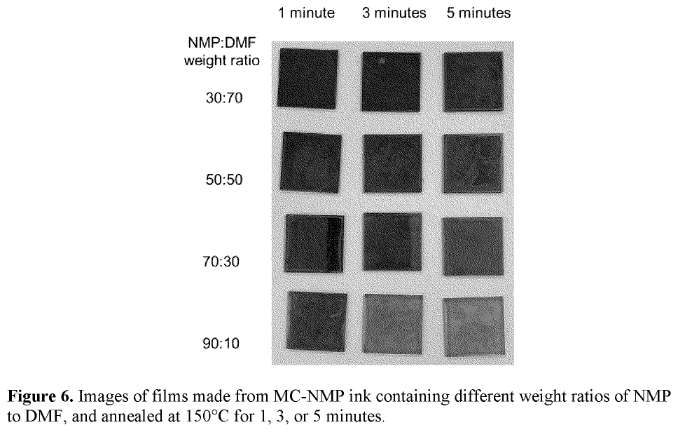

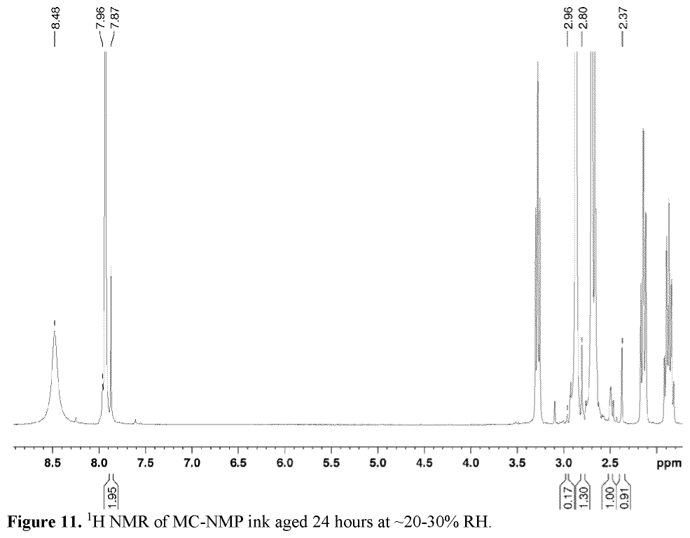

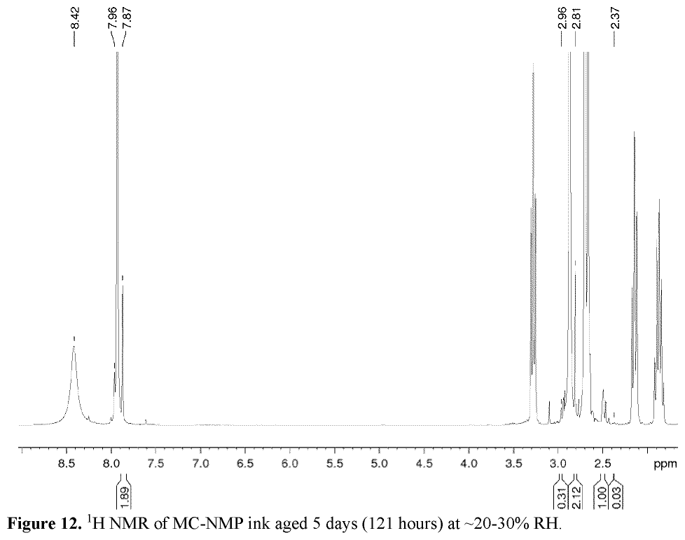

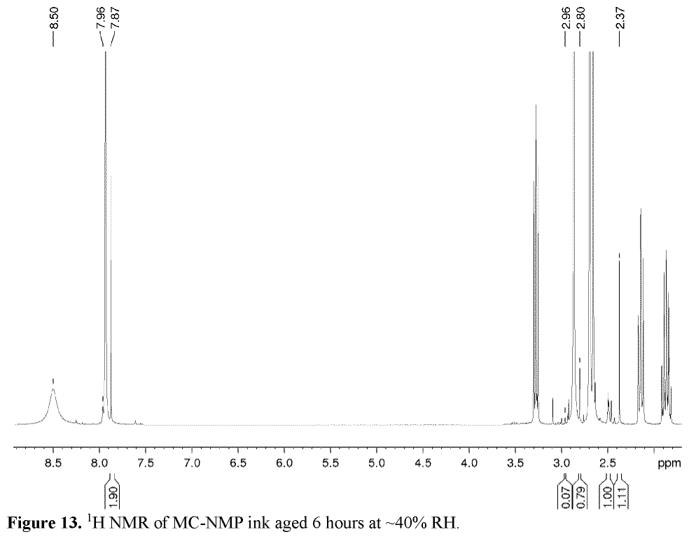

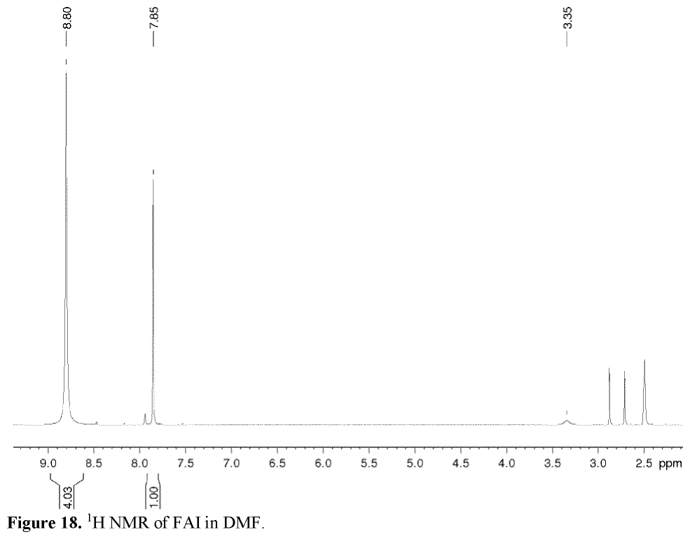

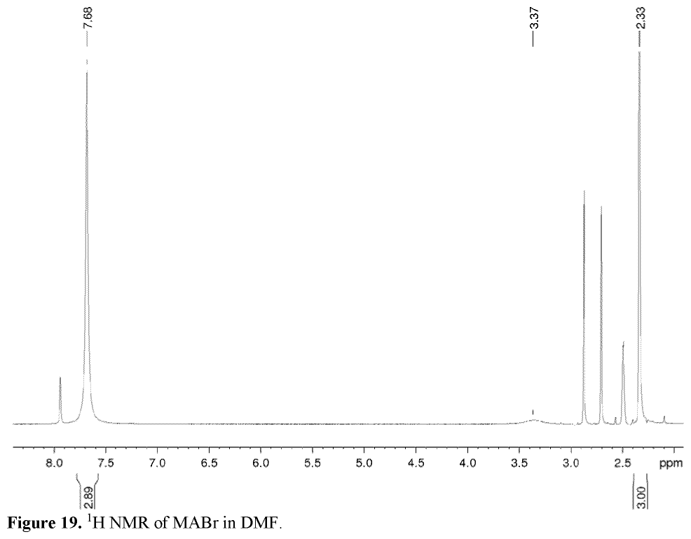

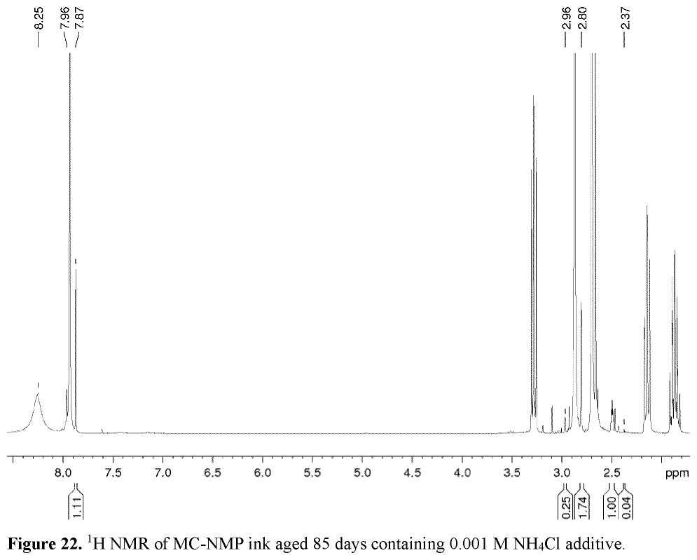

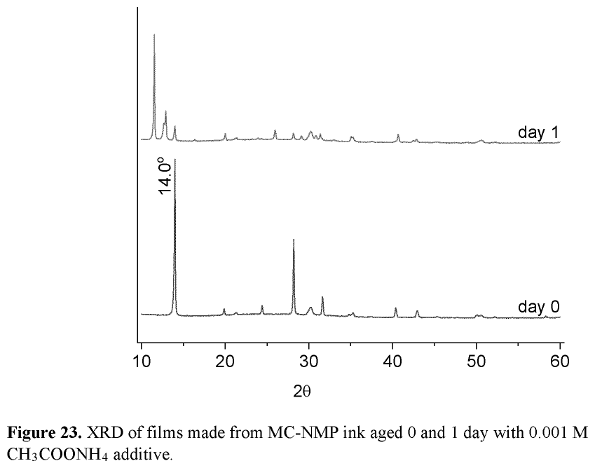

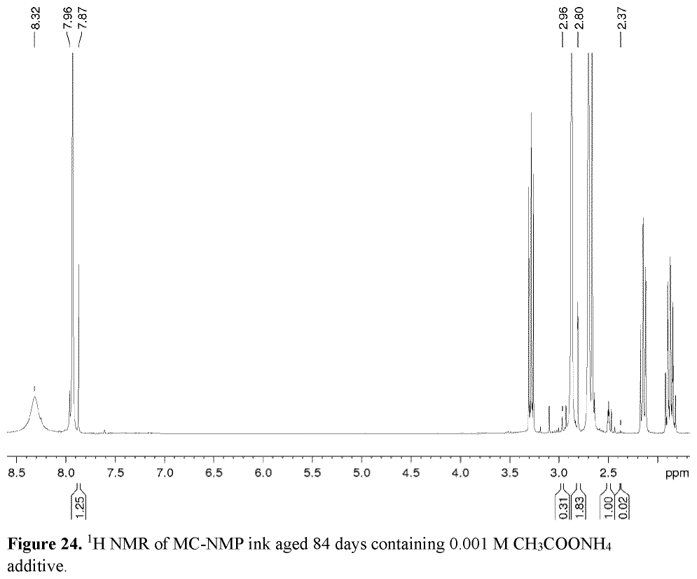

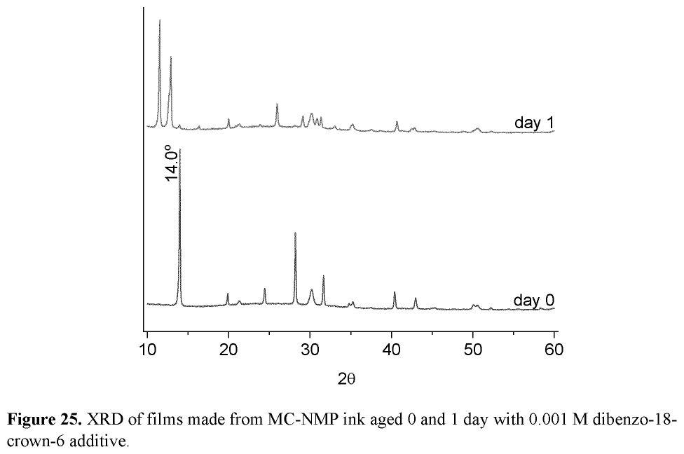

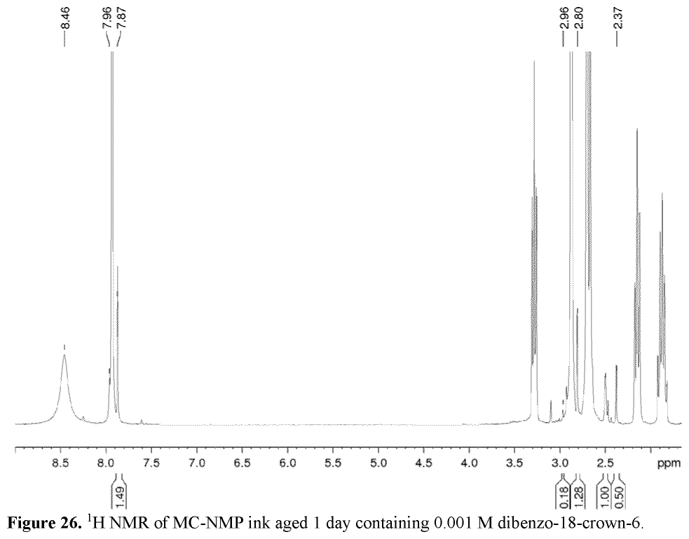

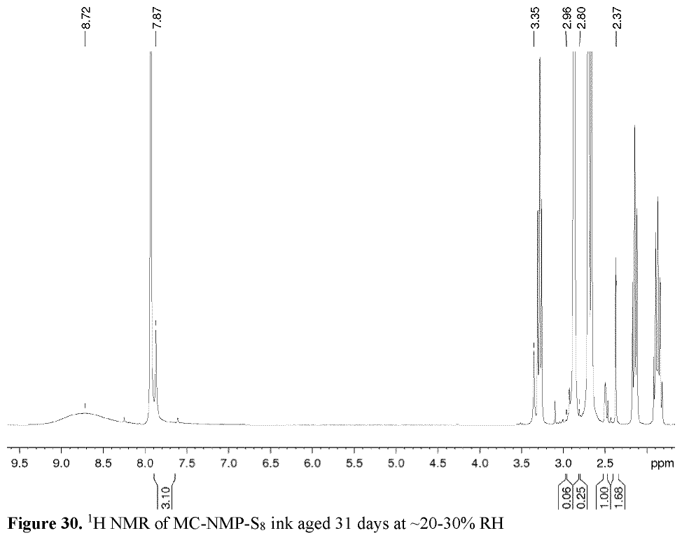

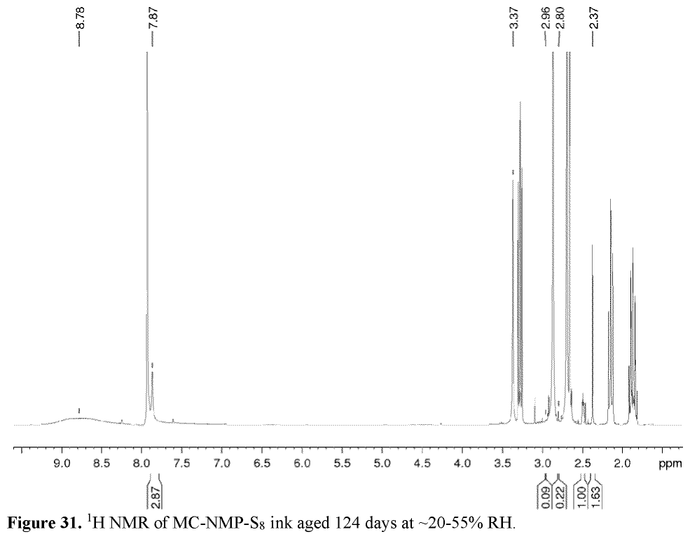

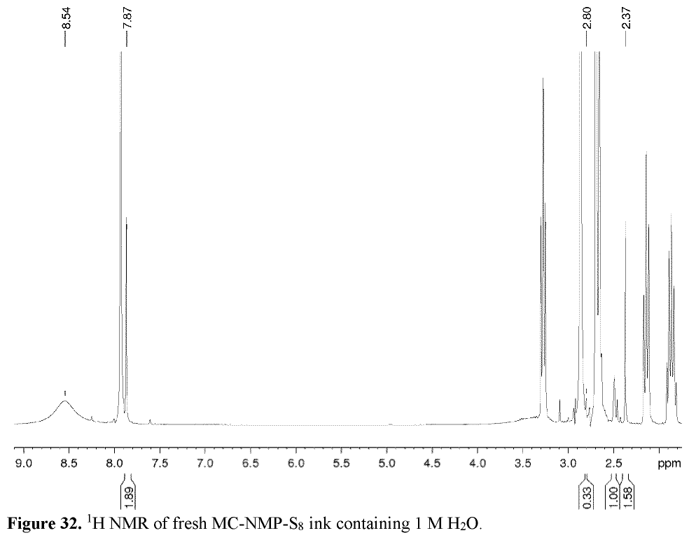

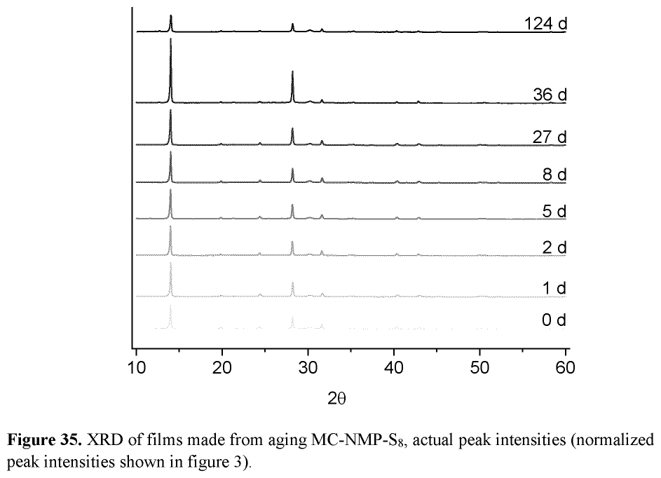

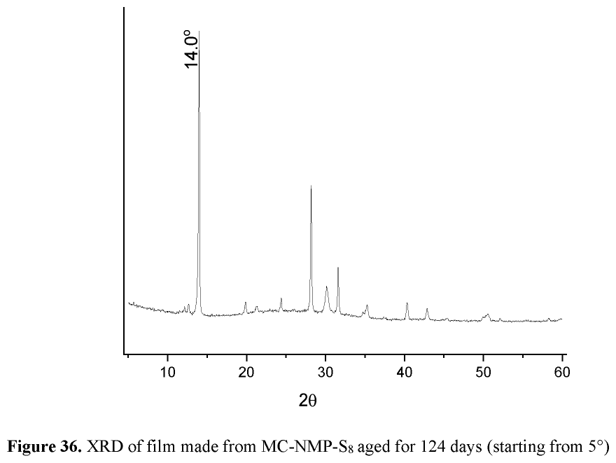

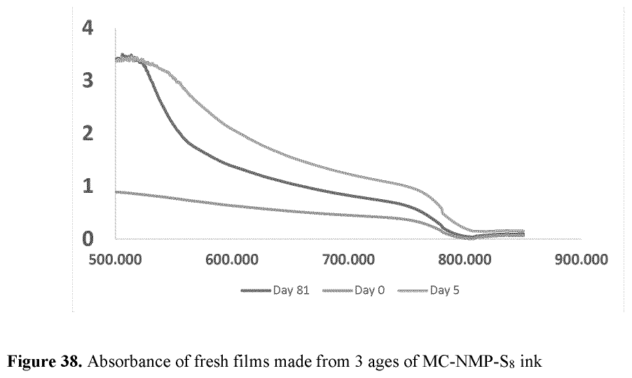

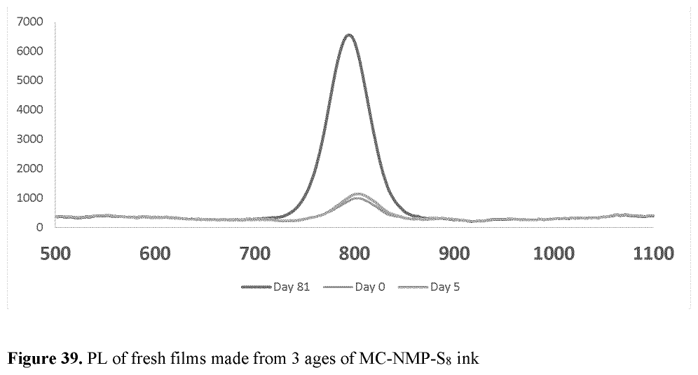

A method of stabilizing perovskite ink will now be described with reference to FIG. 1 through FIG. 5D. In order to ensure that all steps are thoroughly understood supplementary Figures FIG. 6 through FIG. 39 have also been provided as support along with supplementary tables Table SI through Table S3.

Research into Causes of Degradation of Perovskite Ink:

Before addressing the problem of degradation of perovskite ink, we first had to understand the mechanism that causes the degradation.

Proposed ink degradation mechanisms involving MA+, FA+, and solvent begin with the deprotonation of MA+ or FA+ to produce reactive methylamine (MA) or formamidine (FA). Although inhibiting deprotonation with sulfur, triethyl borate or phenylboric acid significantly improved the stability of DMSO/DMF inks, the characteristics of an additive required to confer moisture stability remain to be investigated.

Furthermore, degradation and stabilization studies have previously focussed exclusively on perovskite inks containing DMSO and DMF cosolvent, a composition that was optimized for lab-scale spin-coating of MA+-based perovskites: however, spin coating and the simultaneous removal of excess ink solvent by antisolvent dripping cannot be used to fabricate uniform large-area perovskite films. For the scalable fabrication of PSCs, deposition methods such as blade, slot die, and spray coating are highly desirable. The subsequent perovskite processing window, in which rapid removal of excess ink solvent results in the formation of high-quality perovskite films, should be as long as possible to make reproducible, high-performance PSCs. Using DMF as a cosolvent, but replacing DMSO with N-methyl-2-pyrrolidone (NMP) significantly extends the processing window from several seconds to several minutes or longer. Moreover, interactions between NMP and FAI are stronger than between DMSO and FAI in wet precursor films, resulting in improved film quality when NMP is used as a cosolvent for the FA-dominant perovskite compositionsused in record-breaking small-area devices. These attributes of FA+-based NMP/DMF inks have led to their use in the fabrication of high performing PSCs by scalable deposition methods.

As PSC production moves from research labs to industry, an understanding of the role of water in promoting ink degradation and how to prevent the participation of water in these reactions is needed. In particular, degradation processes should be investigated in perovskite ink compositions compatible with scalable deposition to account for any potential effects on degradation mechanisms.

Here, we show using IH NMR spectroscopy that: scalable perovskite ink containing a mixture of organic cations (3 FA+: 1 MA+) in NMP and DMF (abbreviated as “MC-NMP”) degrades via reaction of MA with FA+ within hours: water increases the reactivity of MA+ by accelerating proton exchange between MA+ and MA; and the addition of elemental sulfur (S8) slows this proton exchange process via sulfur-amine reactions, decreasing the reactivity of MA+. Sulfur-stabilized MC-NMP ink (abbreviated as “MC-NMP-S8”) shows minimal degradation of the organic components over three months of aging at room temperature in ambient air. We report that PSCs fabricated from MC-NMP-S8 inks aged for over one month had comparable performances to PSCs made from fresh MC-NMP ink, and demonstrate the use of MC-NMP-S8 ink to fabricate large area PSCs by blade coating.

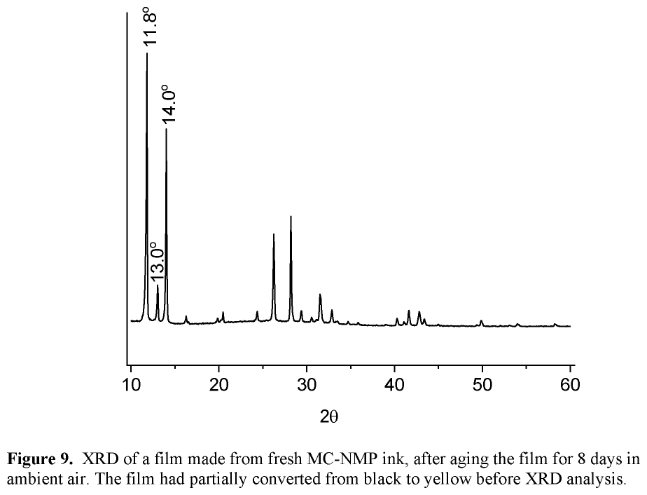

Films made from fresh MC-NMP ink turned black upon annealing due to the formation of perovskite, as indicated by the characteristic X-ray diffraction (XRD) peaks. When the same ink was aged for one day, it formed yellow, non-perovskite films with an XRD peak at 11.7° (FIG. 1A, B). Although the delta (2H) phase has a characteristic peak at 11.8° (FIG. 9), the peak at 11.7° was not from the delta phase as heating it would have caused some conversion to alpha phase. The 11.7° peak is likely a result of the incorporation of organic degradation products from the aged ink, consistent with previous reports. Both films contained some PbI2, evidenced by the low-intensity XRD peak at 12.7°. Additionally, the film from fresh ink has a peak at 12.2° due to the formation of a “6H” polytype initiated by phase segregation, while the film from aged ink has peaks at 11.5° and 12.9° from a “4H” polytype. As the polytype formed by phase segregation is dependent on the FA+ to MA+ ratio in the film, the observation of different polytypes indicates compositional changes to the organic components of MC-NMP when aged.

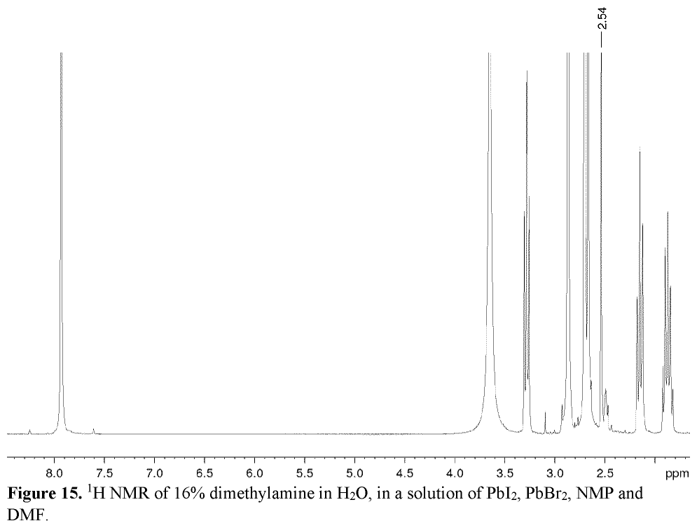

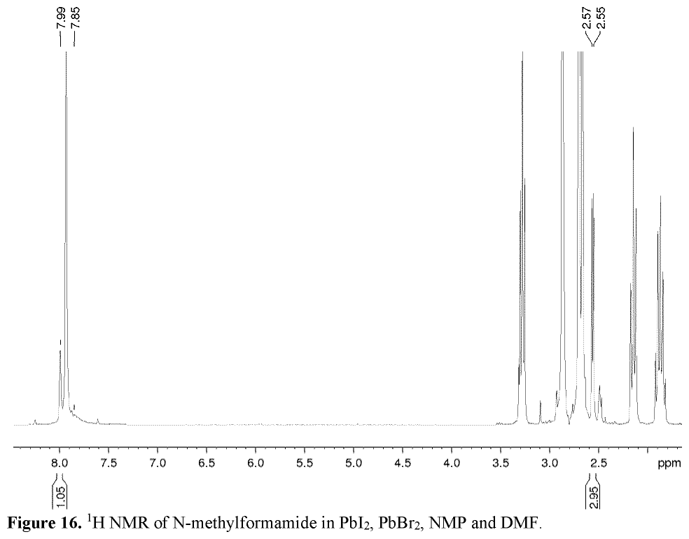

We investigated the precise role of the organic components in MC-NMP degradation by IH NMR spectroscopy. The peaks for the MA+CH3 resonance (2.37 ppm) and FA+CH resonance (7.87 ppm) decreased in intensity over time, in approximately a 3:1 ratio, indicating an equimolar decrease in the concentrations of MA+ and FA+. Concomitant with MA+ and FA+ consumption, new resonances appeared at 2.80, 2.96 and 7.96 ppm (FIG. 1C). The 2.80 ppm and 7.96 ppm signals appeared with a peak area ratio of 3:1, from the CH3 and CH protons of N-methyl formamidinium isomers (“MFA+”), respectively. The 2.96 ppm resonance is from a CH3 group in N,N-dimethyl formamidinium isomers (“DMFA+”). In the 1H NMR spectra of aging MC-NMP ink, we observed no resonances from dimethylamine (at 2.54 ppm, FIG. 15), N-methylformamide (at 2.56 ppm, FIG. 16) or s-triazine (at 9.3 ppm), which would result from the degradation of single organic cation inks containing MA+ or FA+. Thus, these reaction pathways are not involved in the degradation of the mixed MA+ and FA+ ink. The lack of dimethylamine, a product of DMF hydrolysis, also shows that this reaction was not contributing to the degradation of MC-NMP ink.

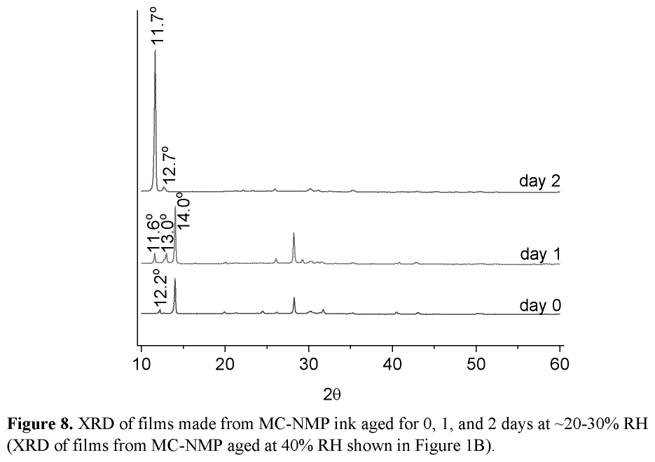

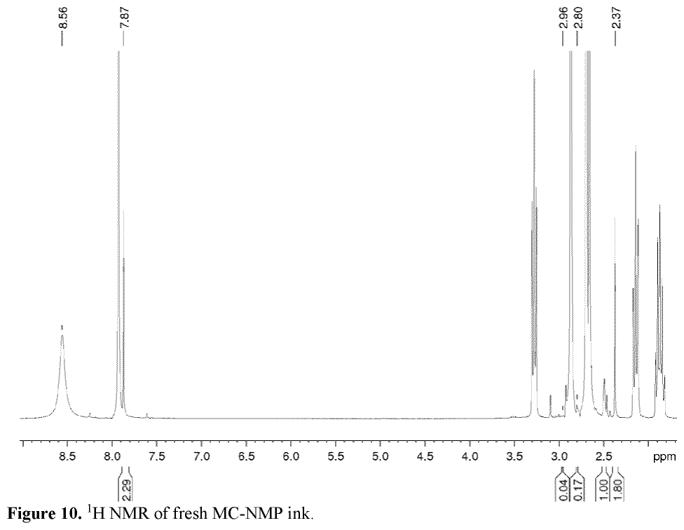

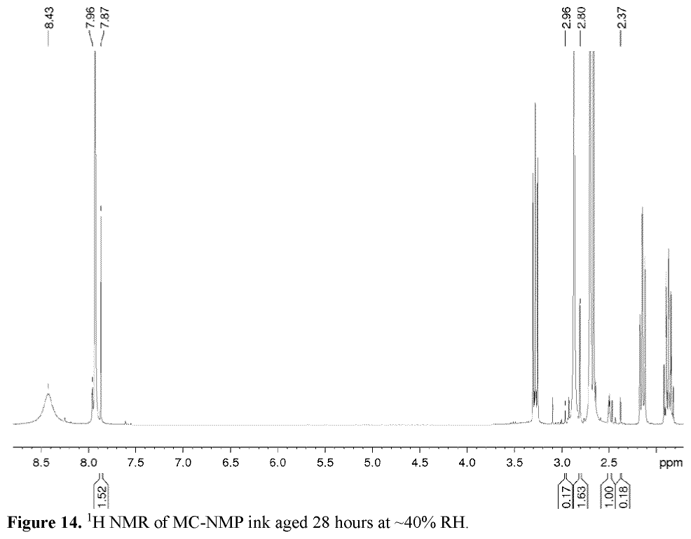

FIG. 1. Degradation of MC-NMP ink in ambient air. (A) Images, and (B) XRD of the corresponding films made from MC-NMP ink aged for 0 and 28 hours at ˜40% relative humidity (RH) (see FIG. 8 for XRD of films from ink aged at low RH). (C) Simplified 1H NMR spectra of MC-NMP ink in dimethyl sulfoxide-d6 (DMSO-d6) aged for 0 and 28 hours, showing only key resonances (see FIGS. 10 and 14 for full spectra, including solvent peaks). (D) Proposed mechanisms for the reactions of MA with FA+ and MFA+. (E) Percentage of MA+ remaining after aging at ˜20-30% RH and ˜40% RH, relative to MA+ in fresh MC-NMP ink (˜20-30% RH), calculated from the MA+CH3 resonance (FIG. 10-14).

After most MA+ was consumed, resonances from the MFA+ and DMFA+CH3 groups exhibited a 9:1 peak area ratio, indicating a 9:1 molar ratio of MFA+ to DMFA+. Aging MA+/FA+ inks in DMSO/DMF cosolvent resulted in the formation of similar ratios of MFA+ and DMFA+, indicating that the use of NMP instead of DMSO did not affect the degradation mechanism. The formation of these degradation products is thought to be initiated by neutral MA, which effects aminolysis of FA+ to produce MFA+ and ammonia, followed by a second aminolysis reaction between MA and MFA+ to produce DMFA+ and ammonia (FIG. 1D). MA and FA, both of which could participate in these reactions, are always present in the perovskite ink at low concentrations as the conjugate bases in their respective acid-base equilibria (equations 1, 2). Fresh MC-NMP ink contains 0.38 M MA+ and 1.2 M FA+: based on the aqueous pKa values for these cations (equations 1, 2), which are strongly correlated and similar in magnitude to their pKa values in polar aprotic solvents such as DMSO, NMP, and DMF, the approximate initial concentrations of MA and FA in MC-NMP ink are 3×10-6 and 2×10-6 M, respectively.

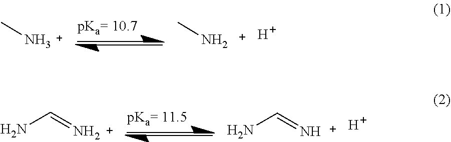

We discovered that ink degradation is significantly accelerated with increased humidity: the half-life of MA+ is ˜14 hours at ˜20-30% relative humidity (RH), in comparison to ˜9 hours at ˜40% RH (FIG. 1E). Given that the ink solvents are very hygroscopic, it is clear that a greater concentration of dissolved water (from the humid atmosphere) accelerates the degradation reactions. Water is not a reactant in the formation of MFA+ and DMFA+ (FIG. 1D), and we do not observe any hydrolysis products: therefore, we posit that water plays an indirect role in facilitating the reactions of MA+ and FA+.

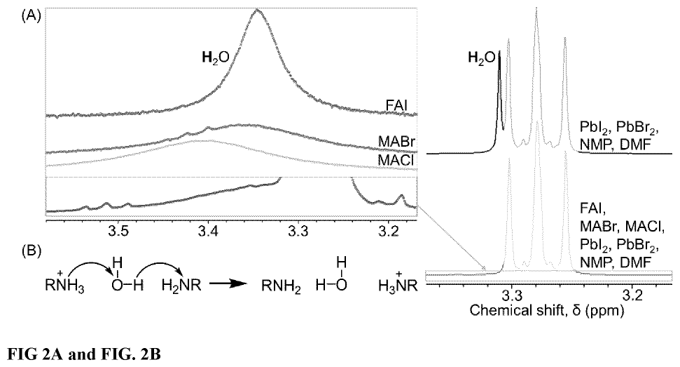

FIG. 2. Amine-water proton exchange. (A) The IH NMR H2O resonance is broad in solutions containing MA+ and/or FA+ (inset), and narrow in spectra of solutions which do not contain MA+ or FA+ (black trace). (B) Amine-water proton exchange process: a proton is transferred from an alkylammonium to water, and water to an alkylamine. This process broadens the 1H NMR water resonance.

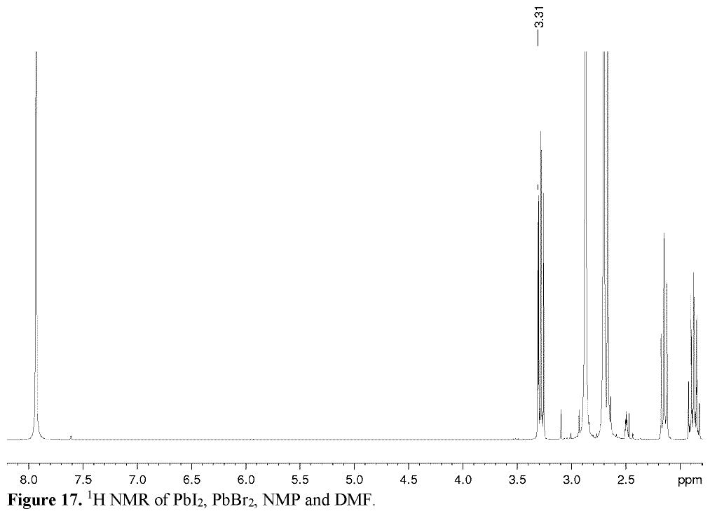

To investigate the role of water in ink degradation, we compared the 1H NMR spectra of solutions containing water with and without MA+ and FA+. In 1H NMR spectra of MC-NMP ink, MABr and MACI solutions, the water resonance is broad, each with a full-width at half maximum (FWHM) of ˜50 Hz, and ˜20 Hz for an FAI solution (FIG. 17-19). On the other hand, water protons in solutions containing all components of MC-NMP ink except for MA+ and FA+ produced a very narrow, ˜1 Hz, resonance (FIG. 2A, 20). Broad peaks are observed for protons undergoing chemical exchange during acquisition of the NMR signal: the FWHM of the resonance for an exchanging proton population is directly related to its rate of exchange. Thus, broadening of the water resonance in the presence of MA+ and FA+ indicates an increased rate of water proton exchange. This can be attributed to the transfer of protons between water and the amino groups of MA+ and FA+.

In the acid-base equilibria of MA+ and FA+, the protonated forms and their conjugate bases are interconverting. In aqueous solutions, the predominant mechanism for this process involves water (FIG. 2B): interconversion by direct proton transfer between the protonated species and their conjugate bases contributes to a lesser extent, and at a slower rate. The exchange of water and N—H protons in MC-NMP ink indicates the involvement of water, suggesting that high water content results in an increasing rate of interconversion. This leads to an accelerated rate of ink degradation, as MA+ and FA+ cations can rapidly be converted to MA and FA which will then engage in aminolysis reactions.

### Stabilization of Ink

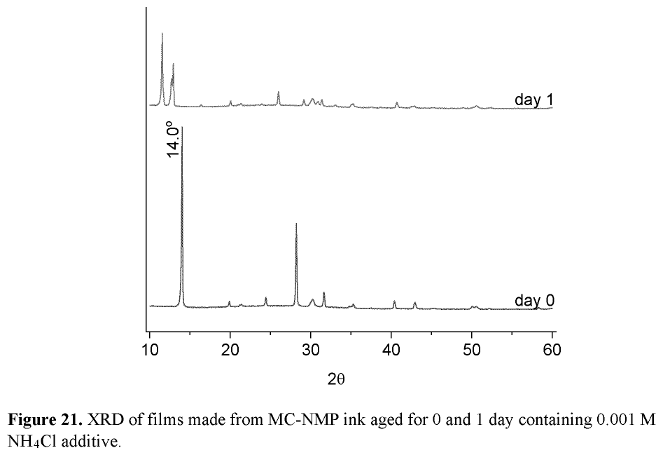

To stabilize the ink, the rate of interconversion between the weak acids and their conjugate bases should be slowed by inhibiting amine-water proton exchange. A reduction in the rate of exchange can be observed by narrowing of the 1H NMR water peak: it becomes easily distinguishable from the baseline, and further slowing proton exchange narrows the water peak until it appears similar to that of amine-free solutions (FIG. 2A). In highly acidic solutions, the rate of amine-water proton exchange is slowed and the acid dissociation equilibrium will be shifted such that lower concentrations of the reactive MA and FA are formed; however, acids lead to alternative ink degradation routes, such as acid catalyzed DMF hydrolysis (FIG. 21-26). Therefore, we investigated neutral additives that could interact with amine groups. The rate of amine proton exchange decreases with increasing alkyl substitution, suggesting that steric hindrance of the amine groups could be effective in improving stability.

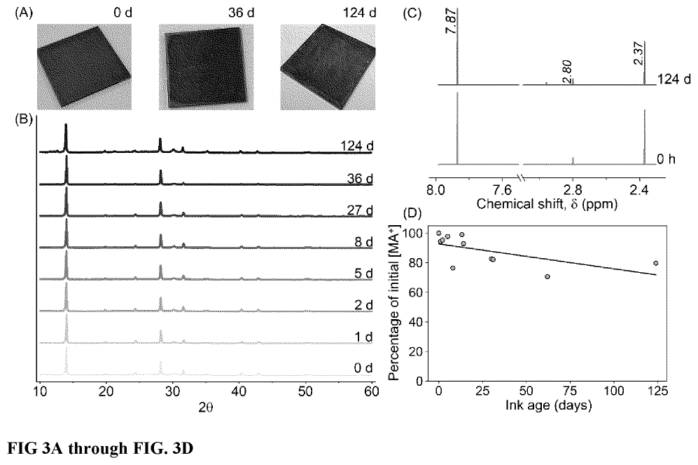

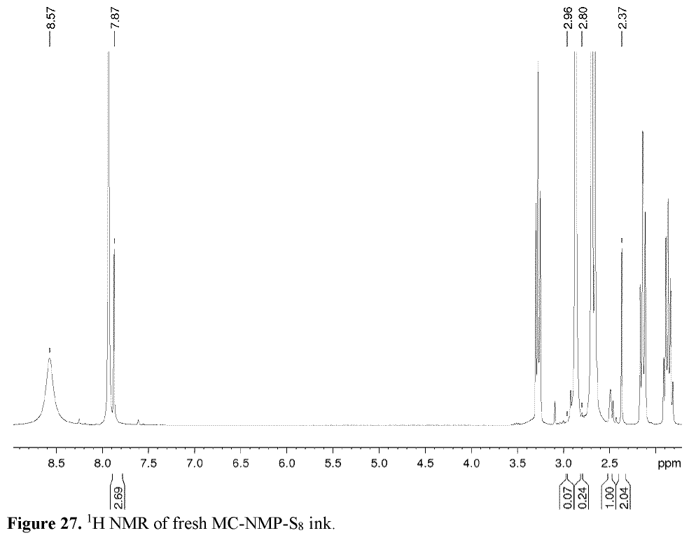

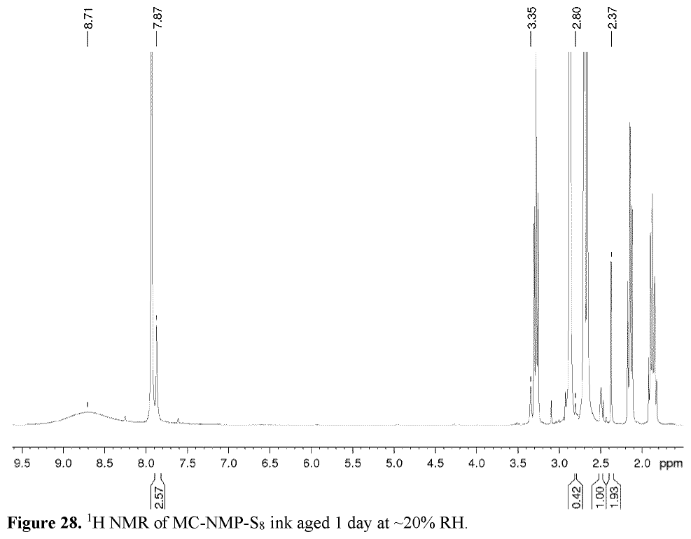

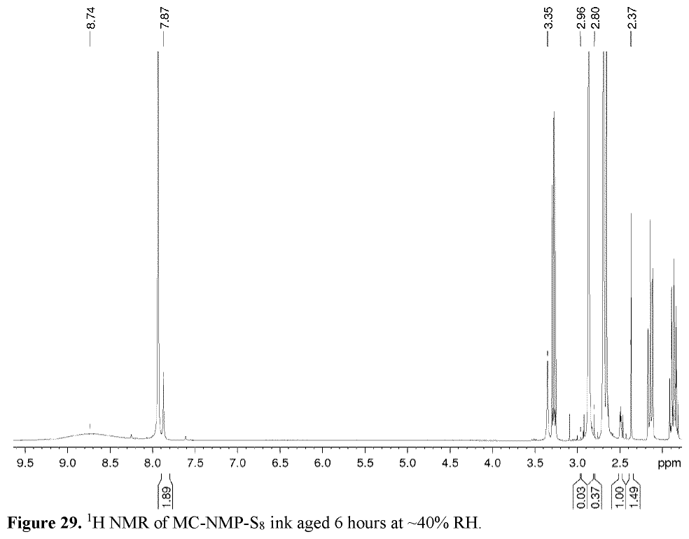

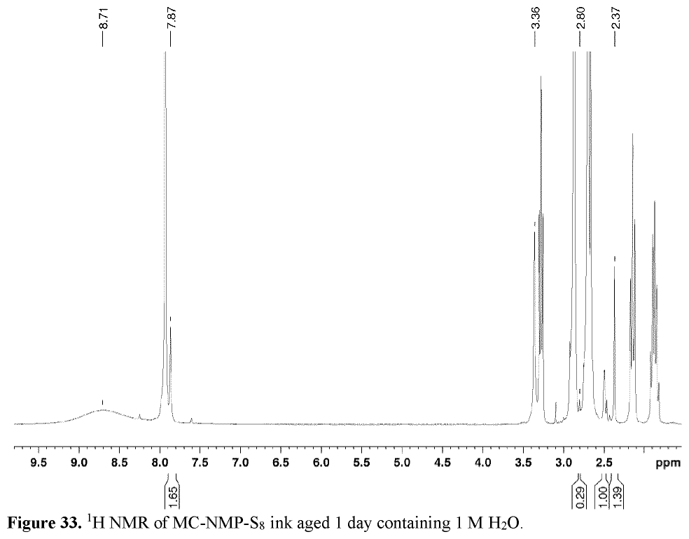

FIG. 3. Stabilization of MC-NMP ink with S8 additive. (A) Images, and (B) XRD of films made from MC-NMP-S8 ink aged for between 0 and 124 days (normalized intensities—see FIGS. 27-28 for actual intensities). (C) Simplified 1H NMR spectra of MC-NMP-S8 ink in DMSO-d6 after 0 and 124 days of aging (at 18-21° C., 15-50% RH), showing only key resonances (see FIGS. 29 and 33 for full spectra, including solvent peaks). (D) Percentage of initial MA+ remaining as a function of ink age, calculated from integrations of the MA+CH3 resonance (FIG. 29-33).

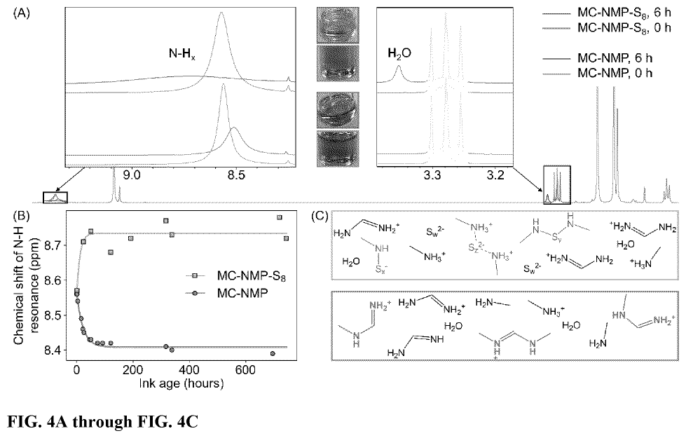

The addition of elemental sulfur (S8) to inks containing FA+ and MA+ in DMSO/DMF cosolvent has been shown to improve their stability due to sulfur-methylamine reactions: however, the exact stabilization mechanism remains to be investigated. The addition of 0.001 M S8 to MC-NMP ink (“MC-NMP-S8”) produced highly stable ink: films made from 124-day aged MC-NMP-S8 formed only perovskite phase (FIG. 3A, B). In IH NMR spectra of aging MC-NMP-S8 ink, the integrations of MA+ (2.37 ppm) and FA+ (7.87 ppm) resonances decreased slightly over 3.5 months (FIG. 3C, D). Extrapolating the minimal change of MA+ content in MC-NMP-S8 indicates an MA+ half-life of ˜6,300 hours (FIG. 3D). Sulfur slowed water-amine proton exchange, evidenced by narrowing of 1H NMR water resonance within the first day of aging (FIG. 4A). Inhibiting acid/base interconversion by slowing water-amine proton exchange resulted in the highly stable ink.

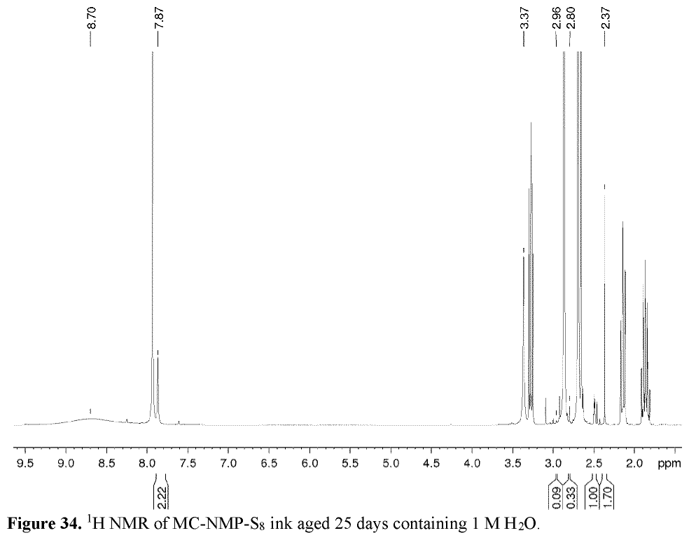

Sulfur must be interacting with water, amine groups, or both to inhibit their proton exchange. To study the role of sulfur-water interactions, we prepared MC-NMP-S8 ink with 1 M water. Despite the 100× higher water concentration than atomic sulfur(S), water-amine proton exchange was still inhibited, stabilizing MA+ and FA+ in the ink for at least 25 days (FIG. 34-36). Given the stability of this ink and the weakness of sulfur-water interactions, we concluded that sulfur-water interactions do not play a role in the inhibition of water-amine proton exchange, and therefore do not contribute to stabilization of the ink.

We also noticed that the orange color of MC-NMP remains unchanged over the first days of aging, while MC-NMP-S8¬ turns from orange to yellow after aging for ˜1 day (FIG. 4A). The color change suggests the formation of open chain polysulfide anions and free radicals, which have been shown to cause color changes upon room temperature dissolution of S8 in aliphatic primary amine solutions. Opening of S8-rings to form these polysulfide species begins with the nucleophilic attack of amines on the S8 ring, to form a N-polythioamine salt with a single N—S bond (equation 3) or a N,N′-polythiobisamine with two N—S bonds (equation 4). Subsequent scission of S—S bonds produces polysulfide ions and radicals, as well as N-polythioamines with shorter polysulfide chains. The weakly acidic H2S (pKa=7) formed in reaction 4 can protonate amines, leading to ionic interactions of the resulting alkylammonium cations with polysulfide anions as “alkylammonium polysulfides” (equation 5).

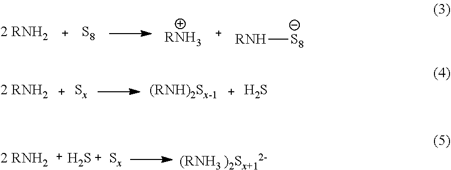

FIG. 4. Interactions of S8 additive with amines in MC-NMP ink. (A) MC-NMP and MC-NMP-S8 inks before and after aging for 6 hours: images of the inks, and corresponding appearances of the N—H and H2O 1H NMR resonances. (B) Change in chemical shift of the N—H resonance as a function of ink age. (C) Amine-sulfur complexes in aged MC-NMP-S8 ink (upper), as opposed to the degradation of aged MC-NMP ink (lower).

The color change of MC-NMP-S8 inks is correlated to a shift and broadening of the N—H resonance in 1H NMR spectra, indicating that as polysulfides form, there is a change in the environment of N—H protons. In the fresh, orange MC-NMP-S8 ink, the N—H peak is similar to that of MC-NMP at 8.57 ppm with a FWHM of 25 Hz: in the 1-day aged, yellow MC-NMP-S8, the N—H resonance shifted to 8.71 ppm and significantly broadened to 170 Hz, which was only observed with the addition of S8 (FIG. 4A, B). Movement of the N—H proton peak to higher chemical shift is most likely due to the formation of N—S containing species, as shown previously by the direct relationship between the N—H chemical shift of aliphatic primary amines and concentration of S8. Shifting and broadening of the N—H resonance, as opposed to the appearance of a new peak, indicates that amine-sulfur complexes are exchanging with amines. These N—S containing species could be N-polythioamines and N,N′-polythiobisamines (equations 3, 4), as formation of their N—S bonds is a reversible process, or alkylammonium polysulfides (equation 5), as polysulfides are labile and rapid exchange between the alkylammonium polysulfide and amine is possible (FIG. 4C). Reactions of sulfur with the amine groups of MA and FA stabilizes them and inhibits the water-accelerated interconversion of MA/MA+ and FA/FA+, decreasing the reactivity of MA+ and FA+ towards the aminolysis reactions that degrade MC-NMP ink.

### Solar Cells

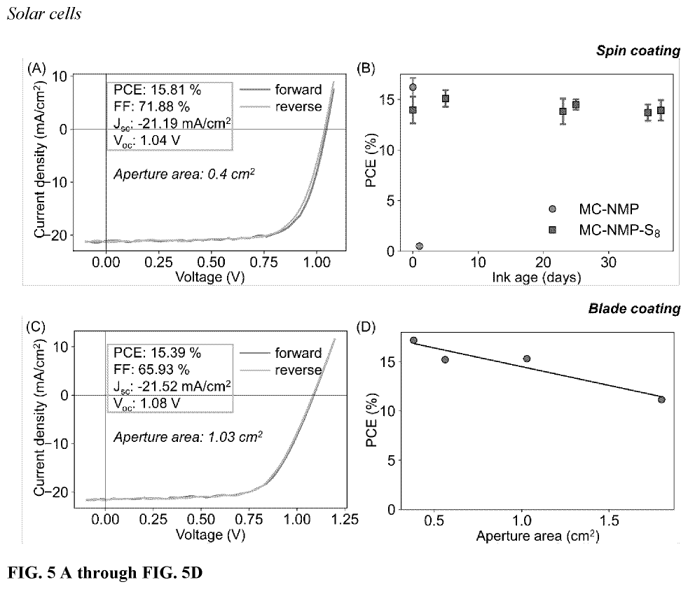

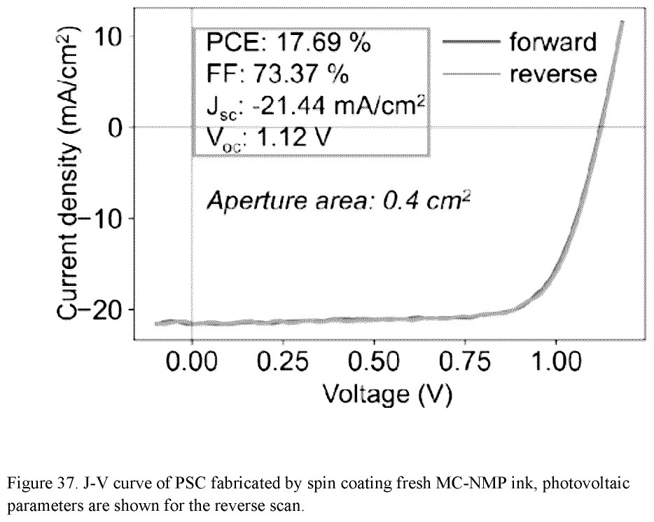

We fabricated PSCs with an indium tin oxide (ITO)/Sn02/(FAPbI3) 0.95 (MAPbBr3) 0.05/Spiro-OMeTAD/Gold (Au) structure. Fresh MC-NMP produced PSCs with an average ˜16% efficiency, −21 mA/cm2 Jsc, 1.10 V Voc and 68% FF (Table S1, FIG. 37). The 1-day aged MC-NMP formed yellow, non-perovskite films (FIG. 1), which could not be used to make PSCs. On the other hand, devices fabricated throughout 38 days of aging MC-NMP-S8 ink consistently delivered an average ˜14% efficiency, −20 mA/cm2 Jsc, 1.05 V Voc and 64% FF (FIG. 5A, B: Table S2).

FIG. 5. PSCs. (A) Current density-Voltage (J-V) curve of PSC fabricated by spin coating MC-NMP-S8 ink aged for 5 days in ambient air, photovoltaic parameters are shown for the reverse scan. (B) Power conversion efficiency (PCE) for an aperture area of 0.4 cm2 as a function of the ink age used to fabricate PSCs (by spin coating) (Note: Non-perovskite films were obtained from aged MC-NMP, as shown in FIG. 1). (C) J-V curve of PSC fabricated by blade coating fresh MC-NMP-S8 ink, photovoltaic parameters are shown for the reverse scan. (D) PCE as a function of aperture area for the measurement of devices fabricated by blade coating fresh MC-NMP-S8 ink (Table S3).

PSCs made by blade coating MC-NMP-S8 demonstrated comparable efficiencies to devices fabricated by spin coating (FIG. 5C: Table S3), indicating the compatibility of the ink for scalable fabrication of solar cells. The blade coated device showed decreased efficiencies (mainly due to a decrease in fill factor) with increased aperture areas (FIG. 5D). This well-known trend of efficiency loss with upscaling is unavoidable in all types of solar cells because the series resistance (Rs), from the sheet resistance of the transparent electrode (e.g., ITO), increases approximately linearly with aperture area. Further optimization of electrode conductivity and absorber thickness should increase the fill factor and photocurrent (similar perovskite compositions can reach a Jsc value of 25 mA/cm2), and hence the overall efficiency of scalable PSCs.

### Materials

Tin (IV) oxide (15% in H2O, Alfa Aesar). Formamidinium iodide (FAI) (>99.99%, Greatcell Solar); lead (II) iodide (99.99%, TCI); methylammonium bromide (MABr) (>99.99%, Greatcell Solar); lead (II) bromide (≥98%, Sigma-Aldrich); methylammonium chloride (MACI) (>99%, Greatcell Solar): 1-methyl-2-pyrrolidinone (NMP) (≥99.0%, Sigma-Aldrich); N,N-dimethylformamide (DMF) (anhydrous, 99.8%, Sigma-Aldrich): sulphur (sublimed, BDH): L-α-phosphatidylcholine (egg yolk, Type XVI-E, ≥99% (TLC), lyophilized powder, Sigma-Aldrich); phenethylammonium iodide (PEAI) (98%, Sigma-Aldrich). 2,2′,7,7′-Tetrakis [N,N-di (4-methoxyphenyl)amino]-9,9′-spiro-bifluorene (spiro-OMeTAD) (Xi'an Polymer Light Technology Corp.); bis(trifluoromethane) sulfonimide lithium salt (Li-TFSI) (99.95%, Sigma-Aldrich): 4-tert-butylpyridine (tBP) (96%, Sigma-Aldrich): FK 209 Co (III) TFSI salt (Co-TFSI) (Sigma-Aldrich). Dimethyl sulfoxide-d6 (DMSO-d6) (99.9 atom % D, Sigma-Aldrich).

### Instrumentation

XRD measurements were done on a PANalytical™ Empyrean system using a Cu (K_{α}, 1.5406 Å) source. 1H NMR spectra were acquired with a Bruker AVANCE™—III 300 MHz spectrometer, with chemical shifts calibrated to the residual DMSO-ds signal. Blade coating was done with a Zehntner Proceq ZAA 2300 Automatic Film Applicator, and photovoltaic parameters were measured with a Newport Oriel sol-3A (class AAA) solar simulator.

### Perovskite Ink

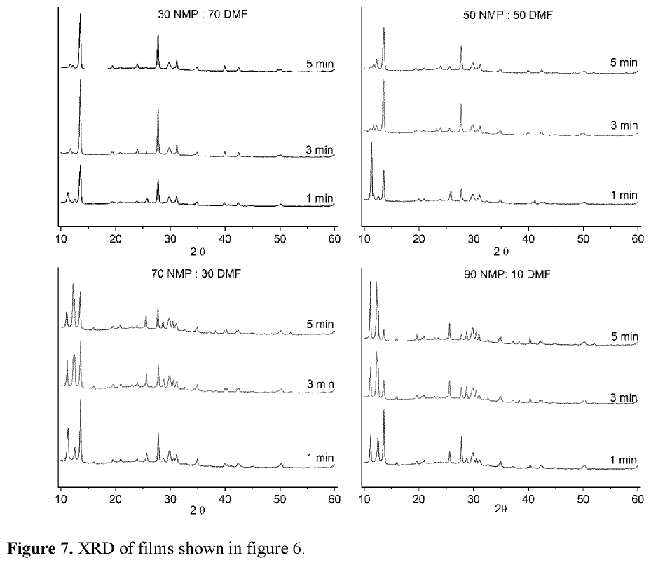

All inks contain 1.23 M FA⁺, 0.382 M MA⁺, 1.29 M Pb²⁺, 3.69 M I⁻, 0.186 M Br⁻ and 0.32 M Cl⁻ in a 30:70 weight ratio of NMP to DMF (optimization of solvent composition shown in FIGS. 6 and 7). Sulfur-containing inks were prepared by making a stock solution of S₈, which was then used to make up a final concentration of 0.001 M S₈ in the ink. In addition to 0.001 M S₈, inks used for blade coating also contain 0.206 mg/mL L-α-phosphatidylcholine. For the acquisition of all 1H NMR spectra, 100 μL of ink was mixed with 500 μL of DMSO-d₆ immediately before analysis. ¹H NMR signals are integrated relative to the residual DMSO-d₅ signal at 2.49 ppm (calibrated to 1.00). Equations for the exponential and linear regression analyses of NMR data (FIGS. 1E, 3D, 4B), calculated using the SciPy library (optimize and stats modules), are as follows:

### FIG. 1E:

y=100e^{-0.05x}+0.2(20-30% RH)

y=100e^{-0.08x}−1(40% RH)

FIG. 3D: y=−0.2x+93

FIG. 4B:

y=−0.2e^{-0.09x}+9(MC-NMP-S₈)

y=0.2e^{-0.04x}+8(MC-NMP)

### Solar Cell Fabrication

Indium tin oxide patterned glass substrates were cleaned by sonication for 15 minutes in each of an extra-water solution, water, acetone, and isopropanol (IPA), followed by 30 minutes of UV/O₃ treatment. The electron transport layer was fabricated from a solution containing a 6:1 volume ratio of H₂O to 15% SnO₂ in H₂O, which was sonicated before deposition by spin coating 100 μL at 3000 rpm for 30 seconds (twice). Water was used to wipe the SnO₂ solution off the substrate edges before annealing at 150° C. for 30 minutes. After another 30 minutes of UV/O₃ treatment, perovskite ink (filtered with 0.22 μm PTFE) was deposited by spin coating (75 μL ink at 4000 rpm for 25 s) or blade coating (20 μl ink, 120 μm gap height, at 7 mm/s), followed by 1 minute in a diethyl ether bath and annealing for 3 minutes at 150° C. Interfacial modification of perovskite layers deposited by blade coating was done by dipping in a solution of 1 mg/mL PEAI in IPA for 1 minute, and subsequently washing the film for 5-10 seconds with IPA and annealing at 100° C. for 1 minute. The hole transport layer was fabricated from a mixture (filtered with 0.22 μm PTFE) containing 0.07 M spiro-OMeTAD in chlorobenzene, 1.88 M Li-TFSI in acetonitrile, 0.25 M Co-TFSI in acetonitrile and tBP in a volume ratio of 110:2.3:1:3.9, which was deposited by dynamic spin coating 70 μL at 2000 rpm for 30 seconds. The perovskite layer and HTL were wiped off the substrate edges with 2-ethoxyethanol before thermal evaporation of gold on the HTL. Samples for XRD analysis were prepared from cleaned ITO-glass substrates, with a SnO₂ and perovskite layer deposited by spin coating as described above. Fabrication and storage of all inks and films was done in ambient air, at room temperature (18-22° C.).

TABLE S1
Photovoltaic parameters of solar cells fabricated by spin
coating fresh MC-NMP ink. Values are averages from 35
pixels with an aperture area of 0.3996 cm², measured
after aging devices for 3 days in a box with desiccant.
FIG. 5B includes data from the reverse scans.

| Scan | | | | |
|---|---|---|---|---|
| direction | PCE (%) | FF (%) | J_{sc} (mA/cm²) | V_{oc} (V) |
| forward | 15.56 ± 1.32 | 66.43 ± 4.15 | −21.27 ± 0.38 | 1.10 ± 0.02 |
| reverse | 16.22 ± 0.90 | 68.92 ± 2.63 | −21.31 ± 0.30 | 1.10 ± 0.02 |

TABLE S2
Photovoltaic parameters of solar cells fabricated by spin coating aging
MC-NMP-S₈ ink; for each set of devices, data is shown for the forward and then
reverse scan direction. Devices were measured with an aperture area of 0.3996
cm² after aging for 6-7 days in a box with desiccant. FIG. 5A includes data
from ink aged for 5 days, and FIG. 5B includes data from the reverse scans.

| Ink age | Number of | PCE | FF | J_{sc} | V_{oc} |
|---|---|---|---|---|---|
| (days) | pixels | (%) | (%) | (mA/cm²) | (V) |
| 0 | 12 | 13.08 ± 0.82 | 63.03 ± 2.39 | −20.28 ± 0.36 | 1.02 ± 0.02 |
| | | 13.95 ± 1.30 | 67.11 ± 3.60 | −20.27 ± 0.40 | 1.02 ± 0.03 |
| 5 | 12 | 14.45 ± 0.93 | 66.70 ± 3.98 | −20.87 ± 0.16 | 1.04 ± 0.02 |
| | | 15.09 ± 0.83 | 69.51 ± 2.56 | −20.85 ± 0.13 | 1.04 ± 0.02 |
| 23 | 30 | 12.92 ± 1.28 | 59.01 ± 4.29 | −19.81 ± 0.40 | 1.10 ± 0.02 |
| | | 13.81 ± 1.26 | 62.90 ± 4.50 | −19.71 ± 0.37 | 1.11 ± 0.02 |
| 25 | 16 | 13.97 ± 0.69 | 67.98 ± 3.06 | −19.51 ± 0.15 | 1.05 ± 0.01 |
| | | 14.49 ± 0.52 | 70.03 ± 2.28 | −19.49 ± 0.17 | 1.06 ± 0.01 |
| 36 | 20 | 12.40 ± 1.32 | 58.94 ± 4.98 | −19.07 ± 0.37 | 1.10 ± 0.02 |
| | | 13.69 ± 0.81 | 64.56 ± 2.97 | −19.07 ± 0.34 | 1.11 ± 0.02 |
| 38 | 18 | 11.30 ± 1.32 | 54.12 ± 5.36 | −21.32 ± 0.28 | 0.98 ± 0.03 |
| | | 13.86 ± 1.00 | 64.42 ± 3.05 | −21.37 ± 0.21 | 1.01 ± 0.03 |

TABLE S3
Photovoltaic parameters of solar cells fabricated by blade coating
fresh MC-NMP-S₈ ink; for each set of devices, data is shown for the
forward and then reverse scan direction. Devices were measured the
same day they were made. The equation for linear regression in FIG.
5D, the reverse scan PCE vs aperture area, is y = −3.8x + 18.3.

| Aperture area | PCE | FF | J_{sc} | V_{oc} |
|---|---|---|---|---|
| (cm²) | (%) | (%) | (mA/cm²) | (V) |
| 0.3825 | 17.25 | 71.72 | −23.10 | 1.04 |
| | 17.19 | 73.00 | −22.83 | 1.03 |
| 0.5625 | 15.16 | 60.80 | −22.78 | 1.09 |
| | 15.22 | 61.20 | −22.75 | 1.09 |
| 1.03 | 15.41 | 66.19 | −21.40 | 1.09 |
| | 15.32 | 66.13 | −21.38 | 1.08 |
| 1.8 | 11.27 | 48.96 | −21.09 | 1.09 |
| | 11.16 | 48.52 | −21.09 | 1.09 |

A further understanding can be gained through a review of supplemental FIGS. 6 through 39, along with a review of supplemental Table SI. Table S2 and Table S3.

FIG. 3B shows XRD of films made from MC-NMP-S8 ink aged for between 0 and 124 days (normalized intensities-see FIGS. 27-28 for actual intensities). FIG. 3C Simplified 1H NMR spectra of MC-NMP-S8 ink in DMSO-d6 after 0 and 124 days of aging (at 18-21° C., 15-50% RH), showing only key resonances (see FIGS. 29 and 33 for full spectra, including solvent peaks). (FIG. 3D) Percentage of initial MA+ remaining as a function of ink age, calculated from integrations of the MA+CH3 resonance (FIG. 29-33).

Sulfur must be interacting with water, amine groups, or both to inhibit their proton exchange. To study the role of sulfur-water interactions, we prepared MC-NMP-S8 ink with 1 M water. Despite the 100× higher water concentration than atomic sulfur(S), water-amine proton exchange was still inhibited, stabilizing MA+ and FA+ in the ink for at least 25 days (FIG. 34-36). Given the stability of this ink and the weakness of sulfur-water interactions, we concluded that sulfur-water interactions do not play a role in the inhibition of water-amine proton exchange, and therefore do not contribute to stabilization of the ink.

FIGS. 8 and 9: shows degradation of perovskite with no additives (sulfur) in the presence of humidity. FIG. 21-26: Ink stabilization by using additive.

In highly acidic solutions, the rate of amine-water proton exchange is slowed and the acid dissociation equilibrium will be shifted such that lower concentrations of the reactive MA and FA are formed; however, acids lead to alternative ink degradation routes, such as acid catalyzed DMF hydrolysis (FIG. 21-26). Therefore, we investigated neutral additives that could interact with amine groups. The rate of amine proton exchange decreases with increasing alkyl substitution, suggesting that steric hindrance of the amine groups could be effective in improving stability.

FIGS. 10 to 14 shows degradation of perovskite film due to amine-water proton exchange reaction when additive e.g. sulfur was not added. FIG. 3B shows XRD of films made from MC-NMP-S8 ink aged for between 0 and 124 days (normalized intensities-see FIGS. 27-28 for actual intensities).

FIG. 3C Simplified 1H NMR spectra of MC-NMP-S8 ink in DMSO-d6 after 0 and 124 days of aging (at 18-21° C., 15-50% RH), showing only key resonances (see FIGS. 29 and 33 for full spectra, including solvent peaks). (FIG. 3D) Percentage of initial MA+ remaining as a function of ink age, calculated from integrations of the MA+CH3 resonance (FIG. 29-33). Sulfur must be interacting with water, amine groups, or both to inhibit their proton exchange. To study the role of sulfur-water interactions, we prepared MC-NMP-S8 ink with 1 M water. Despite the 100× higher water concentration than atomic sulfur(S), water-amine proton exchange was still inhibited, stabilizing MA+ and FA+ in the ink for at least 25 days (FIG. 34-36). Given the stability of this ink and the weakness of sulfur-water interactions, we concluded that sulfur-water interactions do not play a role in the inhibition of water-amine proton exchange, and therefore do not contribute to stabilization of the ink.

FIGS. 15 and 16: shows the degradation pathway in mixd MA+ and Fa+ ink is different from other inks: In the 1H NMR spectra of aging MC-NMP ink, we observed no resonances from dimethylamine (at 2.54 ppm, FIG. 15), N-methylformamide (at 2.56 ppm, FIG. 16) or s-triazine (at 9.3 ppm), 14 which would result from the degradation of single organic cation inks containing MA+ or FA+0.11,14 Thus, these reaction pathways are not involved in the degradation of the mixed MA+ and FA+ ink.

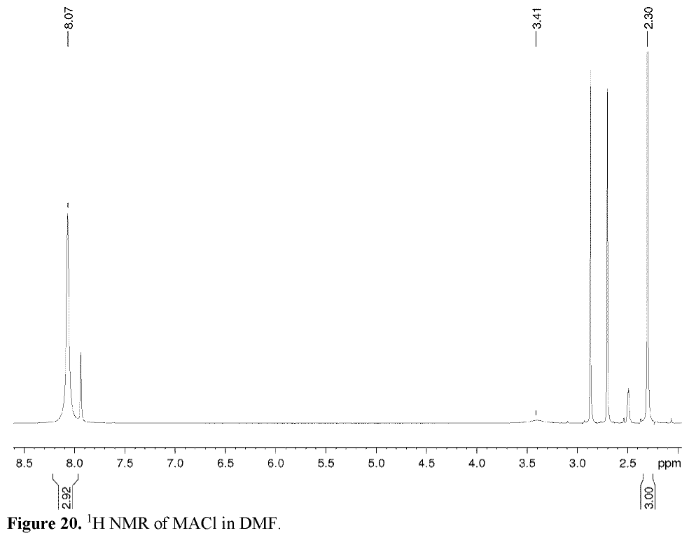

FIGS. 17, 18 and 19: the role of water in ink degradation, of solutions containing water with and without MA+ and FA+. FIG. 20: On the other hand, water protons in solutions containing all components of MC-NMP ink except for MA+ and FA+ produced a very narrow, ˜1 Hz, resonance (FIG. 2A, 20). Broad peaks are observed for protons undergoing chemical exchange during acquisition of the NMR signal: the FWHM of the resonance for an exchanging proton population is directly related to its rate of exchange.

In summary, a major obstacle limiting the commercialization of perovskite solar cells has been the degradation of perovskite inks conventionally used in the fabrication of solar cells by scalable processes: the decomposition of organic cations in perovskite inks is observed within hours in ambient air. We provide evidence that water accelerates the aminolysis of FA+ by MA via facilitation of rapid proton transfer processes, and a low concentration of additive which can interact with the amine groups to inhibit amine-water proton exchange, such as elemental sulfur, stabilizes ink for months. These findings provide a mechanistic understanding of the role of water in ink degradation, offering a tool to overcome perovskite ink instability and paving the way towards the commercialization of perovskite solar cells.

Ambient air processing is desirable for the industrial fabrication of perovskite solar cells. Here we show that perovskite ink containing methylammonium and formamidinium in N-methyl-2-pyrrolidone and N,N-dimethylformamide, a cosolvent composition that satisfies prerequisites for upscaling solar cell fabrication, has a half-life of only 9 hours in ambient air. From 1H NMR spectroscopic analysis, we find that water present in the ink accelerates methylammonium-methylamine proton exchange, facilitating the aminolysis of formamidinium by methylamine. The addition of elemental sulfur inhibits this proton exchange process via sulfur-amine reactions, resulting in stable perovskite ink with a half-life of 6,300 hours. The control ink aged for one day does not form perovskite films for solar cell fabrication, while sulfur-stabilized ink is reproducibly used to make devices with efficiencies >15% when aged for over one month. The stabilized ink is suitable for upscaling perovskite solar cell fabrication, with efficiencies up to 17% for blade-coated devices.

There is provided a method of stabilizing perovskite ink, comprising adding to perovskite ink an additive which can interact with amine groups in the perovskite ink to inhibit amine-water proton exchange. In some embodiment, the additive is elemental sulfur.

There is provided a perovskite ink formulation, comprising precursor salts dissolved in solvent(s), which is deposited as a thin film and crystallized to form the perovskite structure with an ‘ABX3’ composition, wherein: ‘A’ is a monovalent cation such as methylammonium (MA+), formamidinium (FA+) or Cesium (Cs+), ‘B’ is a divalent cation (Pb2+ or Sn2+), and ‘X’ is a halogen (F—, I—, Br— or Cl—); and wherein an additive interacts with amine groups in the perovskite ink to inhibit amine-water proton exchange. The ink may further comprising one or more combinations of salts from the group-A, group-B, added in the molar ratio of 1:1:3 to form the perovskite precursor salts which will later form a thin film of perovskite.

The perovskite ink formulation wherein the perovskite ink comprises one or more additives selected from the group consisting of sulfur or sulfur based compound may be added for stabilization of ink. Examples of other additives to stabilize the ink are triethyl borate, 18-crown-6, ITIC-Th, L-α-phosphatidylcholine, and phenylboric acid, the additive being added in a concentration of about 0.001M to about 0.1M. The additive-containing ink can have additive molarity varies between 10-4M to 1 M. In some embodiments, the perovskite ink formulation may contain 0.001 M sulfur.

The ‘A’ in the perovskite ink formulation may a mixture of methylammonium (MA+) and formamidinium (FA+). The ratio of MA+ to FA+ may vary between 1:19 to 1:1. The ratio of MA+ to FA+ may be 1 to 3.

The perovskite ink precursor may comprise one or more solvents selected from the group consisting of N-methyl-2-pyrrolidone (NMP), alkyl-2-pyrrolidone, N,N-dimethylformamide (DMF), dimethylsulfoxide (DMSO), dialkylformamide, γ-butyrolactone (GBL), 2-methylpyrazine (2-MB), 1-pentanol (1-P), 2-methoxyethanol (2-ME) and N, N′-Dimethylpropyleneurea (DMPU). The weight percentage ratio of selected one or combination of solvents may range from 10-30% to achieve the final concentration of perovskite ink required for the formation of a perovskite thin film.

The solvent in the perovskite ink formation may be a mixture of NMP and DMF. The ratio of NMP to DMF can vary between 5:95 to 50:50. The ratio of NMP to DMF solvents is 30 to 70

In some embodiments, the ‘B’ in the perovskite ink formulation may be a divalent cation comprising of one or more metals from the group of Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, Zr.

In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be one and only one of the elements.

The scope of the claims should not be limited by the illustrated embodiments set forth as examples, but should be given the broadest interpretation consistent with a purposive construction of the claims in view of the description as a whole.

1-19. (canceled)

20. A method of synthesizing a stable perovskite ink, the method comprising:
mixing methylammonium and formamidinium in a solvent comprising N-methyl-2-pyrrolidone (NMP) and N,N-dimethylformamide (DMF) to provide a perovskite ink; and
adding to the perovskite ink elemental sulfur, thereby synthesizing the stable perovskite ink.

21. The method of claim 20, wherein the solvent consists of NMP and DMF.

22. The method of claim 21, wherein the weight ratio of NMP to DMF is 30 to 70.

23. The method of claim 22, further comprising adding L-α-phosphatidylcholine to the perovskite ink.

24. A perovskite ink for use in blade coating, comprising:
precursor salts dissolved in one or more solvents that when deposited as a thin film crystallize to form the perovskite structure with an ‘ABX3’ composition in which:
‘A’ is a mixture of methylammonium (MA+) and formamidinium (FA+);
‘B’ is a divalent cation;
‘X’ is a halogen being one or more of F—, I—, Br— and Cl—;
elemental sulfur; and
a solvent comprising NMP and DMF.

25. The perovskite ink of claim 24, where the molar ratio of MA+ to FA+ is 1 to 3.

26. The perovskite ink of claim 25, wherein the solvent consists of NMP and DMF.

27. The perovskite ink of claim 26, wherein the weight ratio of NMP to DMF is 30 to 70.

28. The perovskite ink of claim 27 further comprising L-α-phosphatidylcholine.

29. A method of synthesizing a perovskite solar cell, the method comprising: selecting a glass substrate; fabricating an electron transport layer on the glass substrate; blade coating the electron transport layer with a perovskite ink comprising methylammonium, formamidinium, N-methyl-2-pyrrolidone (NMP), N,N-dimethylformamide (DMF) and elemental sulfur to provide a perovskite layer; and depositing a hole transport layer on the perovskite layer.

30. The method of claim 29, wherein the method is a scalable method.

31. The method of claim 30, wherein the solvent consists of NMP and DMF.

32. The method of claim 31, wherein the perovskite ink further comprises L-α-phosphatidylcholine.
